(19) United States
(12) Patent Application Publication
(10) Pub. No.: US 2012/0132968 A1
(43) Pub. Date: May 31, 2012

(54) SEMICONDUCTOR DEVICE AND METHOD FOR MANUFACTURING THE SAME

(75) Inventor: Woong CHOI, Seoul (KR)

(73) Assignee: Hynix Semiconductor Inc., Icheon (KR)

(21) Appl. No.: 13/279,060

(22) Filed: Oct. 21, 2011

(30) Foreign Application Priority Data
Nov. 29, 2010 (KR) 10-2010-0120050

(51) Int. Cl. H01L 29/92

(52) U.S. Cl. 257/296; 257/532; 257/E29.342; 257/E29.343

(57) ABSTRACT

A semiconductor device and a method for manufacturing the same are disclosed. The method for manufacturing a semiconductor device includes forming a device isolation film defining an active region over a semiconductor substrate including a periphery region, forming a gate pattern over the active region, forming a contact plug coupled to each of the gate pattern and the active region, forming a line coupled to the contact plug and a first reservoir capacitor over the same layer as in the line, and forming a second storage capacitor coupled to the first storage capacitor. The semiconductor device sufficiently endures a high bias not only using a line electrode and a dielectric film of a periphery region but also using a MOS-type storage capacitor of an upper electrode, and couples a cylindrical storage capacitor in series to a MOS-type capacitor so that it can be used in a small region.

### CROSS-REFERENCE TO RELATED APPLICATION

The priority of Korean patent application No. 10-2010-0120050 filed on 29 Nov. 2010, the disclosure of which is hereby incorporated in its entirety by reference, is claimed.

### BACKGROUND OF THE INVENTION

Embodiments of the present invention relate to a semiconductor device and a method for manufacturing the same.

In a semiconductor device, such as a Dynamic Random Access Memory (DRAM), it is necessary to reduce the area occupied by the semiconductor device in proportion to an increasing integration degree while maintaining electrostatic capacitance. Generally, there are a variety of methods to guarantee sufficient cell electrostatic capacitance in a given area, including, for example, a method for using a high dielectric material as a dielectric film, a method for reducing a thickness of the dielectric film, a method for increasing a surface area of a lower electrode, etc. However, the method for using the high dielectric material requires a great deal of investment, for example, for the development of new material, for the development of new equipment compatible with the new material, for installation of the new equipment, for a test to verify reliability and productivity of the new system, for set-up of optimum processing conditions, etc. Accordingly, the method for increasing the surface area has an advantage in that a conventional dielectric film can be used and the implementation of a fabrication process becomes relatively easier. As a result, this method has been widely used in the actual fabrication process.

There are a variety of methods for increasing an effective region, i.e., a surface area, of the lower electrode. For example, a method for configuring a lower electrode in the form of a three-dimensional (3D) structure (such as a cylinder or a fin), a method for growing a Hemi Spherical Grain (HSG) on a lower electrode, a method for increasing the height of a lower electrode, etc. However, in the method for growing the HSG it may be difficult to guarantee a predetermined distance between lower electrodes. For example, a bridge may form between lower electrodes, so that it is difficult to employ the aforementioned HSG growing method to a semiconductor device formed under a design rule of 0.14 μm or less. Therefore, in general, in order to increase cell capacitance, methods for configuring a lower electrode in the form of a 3D structure and increasing the height of the lower electrode have been widely used. A representative example of such methods is a method for forming a cylindrical lower electrode or a stack-shaped lower electrode.

The above-mentioned cylindrical and stack-shaped electrodes may use the whole outer surface of the electrode or both of the whole outer and the whole inner surfaces as an effective area, and are thus advantageous for increasing the affective area. However, cylindrical or stacked electrodes having an integrated one cylinder stack (OCS) structure are short in height. When height increases, the lower electrode is likely to fall down or be broken even before a dielectric film is formed thereon.

In order to prevent the lower electrode from falling down, the cylindrical lower electrodes must be formed thick.

However, if the cylindrical lower electrode is formed too thick, it is difficult to securely form the dielectric film and an upper electrode over the lower electrode within a given area. In order to guarantee sufficient capacitance, high dielectric material is used. However, high-dielectric materials are disadvantageous because they may cause low productivity and lifting problems.

In the course of operation, power sources are provided not only to a capacitor of a cell region but also to other regions, such as a periphery region. When power is provided to neighboring elements, noise is likely to occur. In order to remove such noise, reservoir capacitors have been widely used. Such reservoir capacitors can be simultaneously formed in a cell region and in a periphery region. Generally, the reservoir capacitor uses a planar type metal-on-silicon (MOS) capacitor composed of a gate and a source/drain. The MOS-type capacitor is used because a gate oxide film shows good inner pressure characteristics when a given voltage is applied to both ends of the capacitor. However, as the integration degree of the semiconductor device increases, the area of the MOS-type capacitor formed in the semiconductor device is reduced accordingly. Capacitance of the MOS-type capacitor is also reduced in proportion to the reduction in area. Thus, a MOS-type capacitor is not appropriate for use as a reservoir capacitor in a highly integrated device. That is, while the conventional MOS-type capacitor has good inner pressure characteristics, it has relatively low capacitance in a given area, and thus the MOS-type capacitor is not proper for use as a reservoir capacitor in a highly-integrated semiconductor device.

Therefore, it is preferable to use a cylindrical capacitor employing a high-dielectric film as a reservoir capacitor in a highly integrated device to improve capacitance. However, in such a device, a voltage applied to the reservoir capacitor of the periphery region (i.e., a peripheral circuit region) is set at a low level, and a high-dielectric film is formed as a thin film to improve the refresh sensing margin, thus a breakdown voltage (BV) becomes too low to use a bias of Vcore or higher in the memory.

### BRIEF SUMMARY OF THE INVENTION

Various embodiments of the present invention are directed to providing a semiconductor device and a method for manufacturing the same that substantially obviate one or more problems due to limitations and disadvantages of the related art.

An embodiment of the present invention relates to a semiconductor device that sufficiently endures a high bias not only using a line electrode and a dielectric film of a periphery region but also using a MOS-type storage (reservoir) capacitor of an upper electrode, and couples a cylindrical storage capacitor in series to a MOS-type capacitor so that it can be used in a small region, and a method for manufacturing the same.

In accordance with an aspect of the present invention, a method for manufacturing a semiconductor device includes forming a device isolation film defining an active region over a semiconductor substrate including a periphery region; forming a gate pattern over the active region; forming a contact plug coupled to each of the gate pattern and the active region; forming a line coupled to the contact plug and a first storage capacitor over the same layer as in the line; and forming a second storage capacitor coupled to the first storage capacitor.

The method may further include, after forming the gate pattern, forming a first insulation film over the gate pattern and the semiconductor substrate; and etching the first insulation film until the gate pattern is exposed.

The method may further comprise, after etching the first insulation film, forming a second insulation film over the gate pattern and the first insulation film.

The formation of the first storage capacitor may further include sequentially depositing a first metal electrode, a dielectric film, and a second metal electrode over the second insulation film; and etching the second metal electrode, the dielectric film, and the first metal electrode using a line formation mask.

The first metal electrode may include tungsten (W), titanium (Ti), titanium nitride (TiN), polymer (Polymer), cobalt (Co) or nickel (Ni).

The method may further include, after forming the first storage capacitor, forming an etch stop film over the first storage capacitor and the line.

The method may further include, after forming the etch stop film, forming a third insulation film over the etch stop film; and forming a lower electrode region by etching the third insulation film until the first storage capacitor is exposed.

The first storage capacitor may include a MOS-type capacitor.

The second storage capacitor may include a cylindrical capacitor.

In accordance with another aspect of the present invention, a semiconductor device includes a first insulation film and a second insulation film formed over a semiconductor substrate including a periphery region; a gate pattern formed in the first insulation film; a first storage capacitor formed over the second insulation film; and a second storage capacitor coupled to the first storage capacitor.

The first storage capacitor may include a MOS-type capacitor.

The first storage capacitor may include a first metal electrode, a dielectric film, and a second metal electrode.

The first metal electrode may include tungsten (W), titanium (Ti), titanium nitride (TiN), polymer (Polymer), cobalt (Co) or nickel (Ni).

The second storage capacitor may include a cylindrical capacitor.

The semiconductor device may further include a contact plug coupled to each of the gate pattern and the semiconductor substrate.

The contact plug may be coupled to a conductive line.

It is to be understood that both the foregoing general description and the following detailed description of the present invention are exemplary and explanatory and are intended to provide further explanation of the invention as claimed.

### BRIEF DESCRIPTION OF THE DRAWINGS

FIGS. 1A to 1K are cross-sectional views illustrating a semiconductor device and a method for manufacturing the same according to an embodiment of the present invention. In each of FIGS. 1A to 1K, (i) shows a cell region, and (ii) shows a periphery region.

### DESCRIPTION OF EMBODIMENTS

Reference will now be made in detail to embodiments of the present invention, examples of which are illustrated in the accompanying drawings. Wherever possible, the same reference numbers will be used throughout the drawings to refer to the same or like parts. A semiconductor device and a method for manufacturing the same according to an embodiment of the present invention will hereinafter be described with reference to the appended drawings.

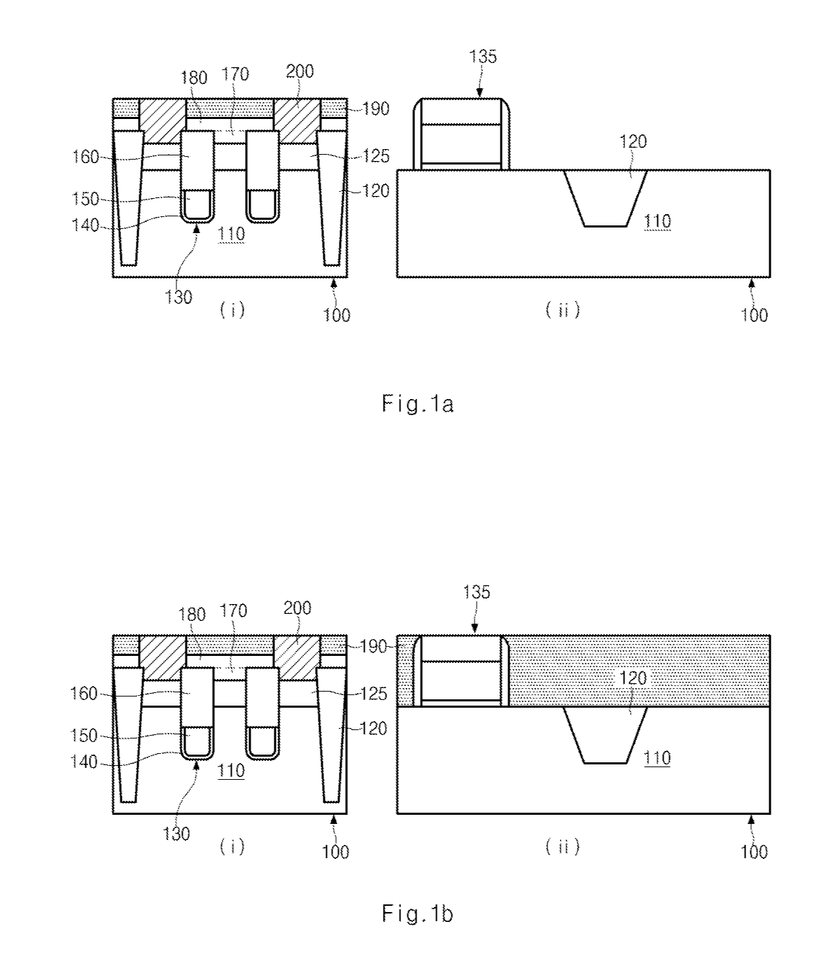

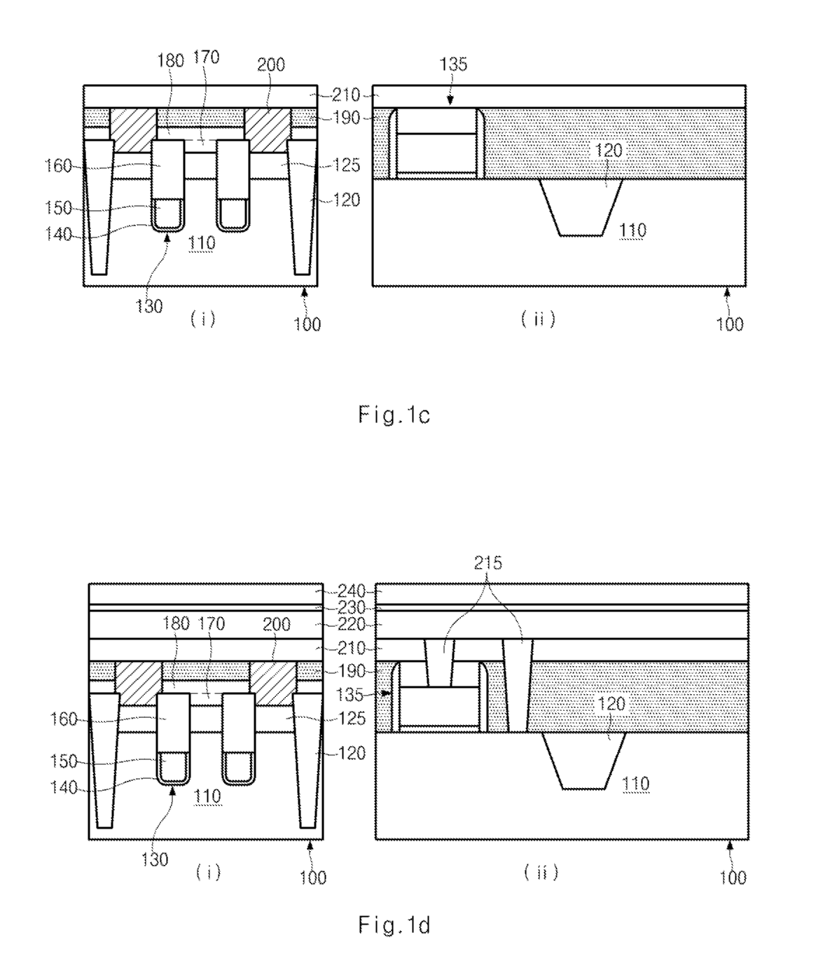

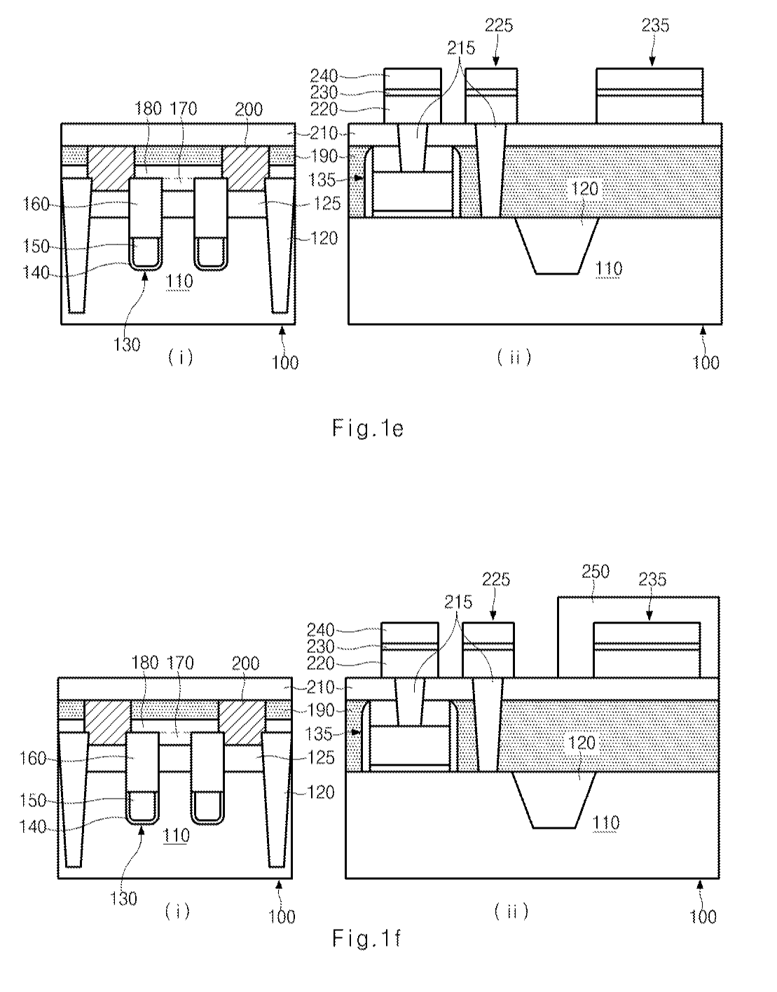

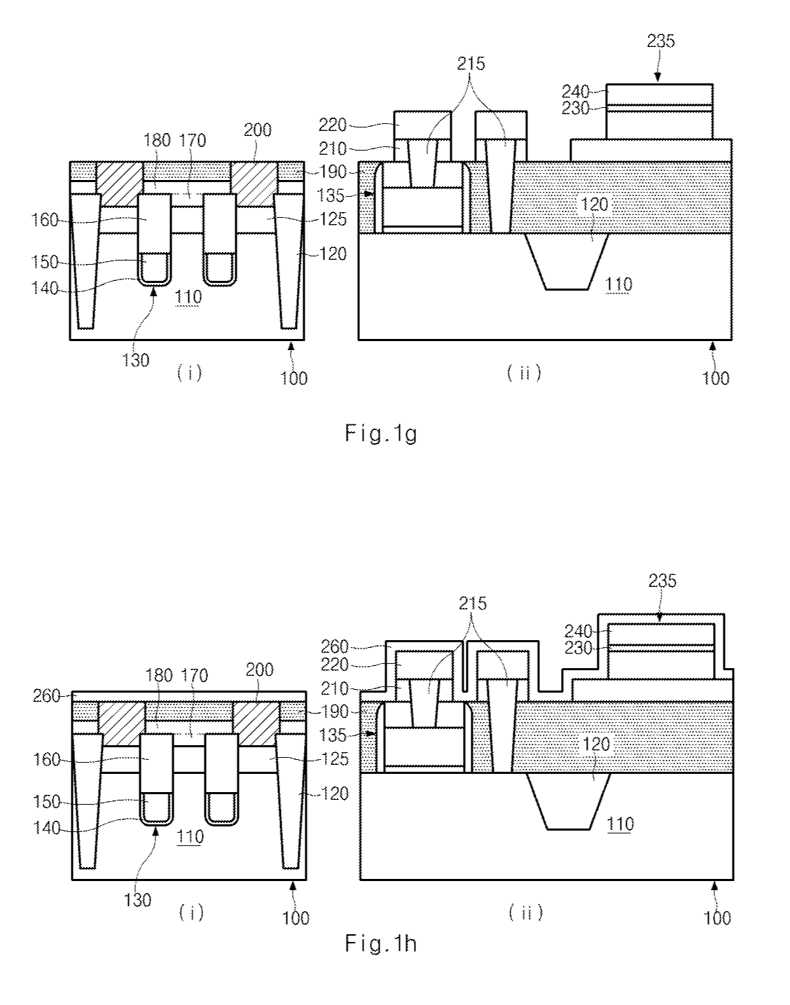

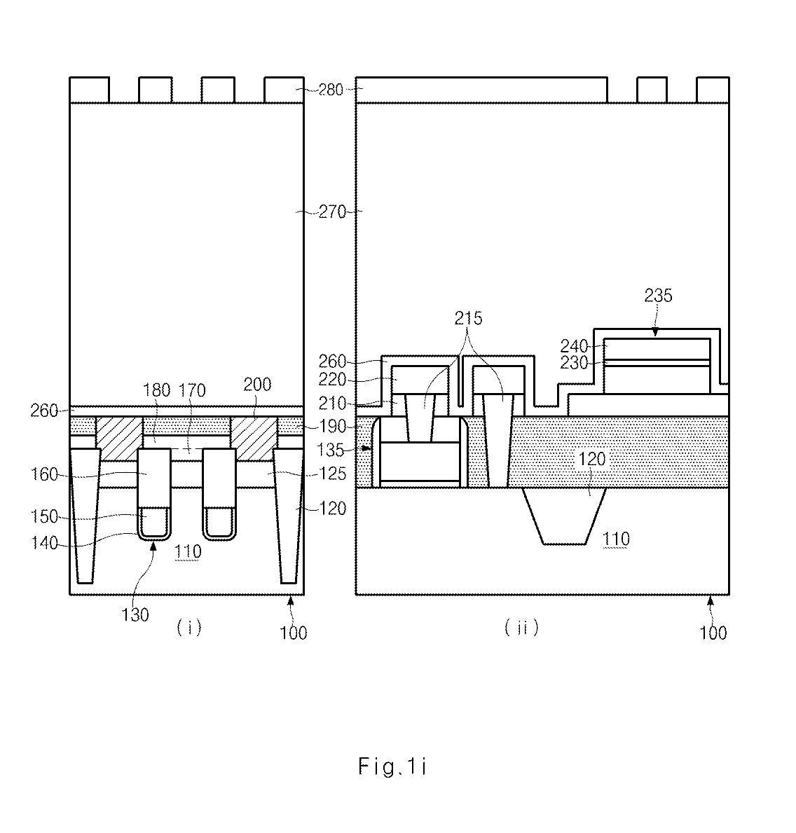

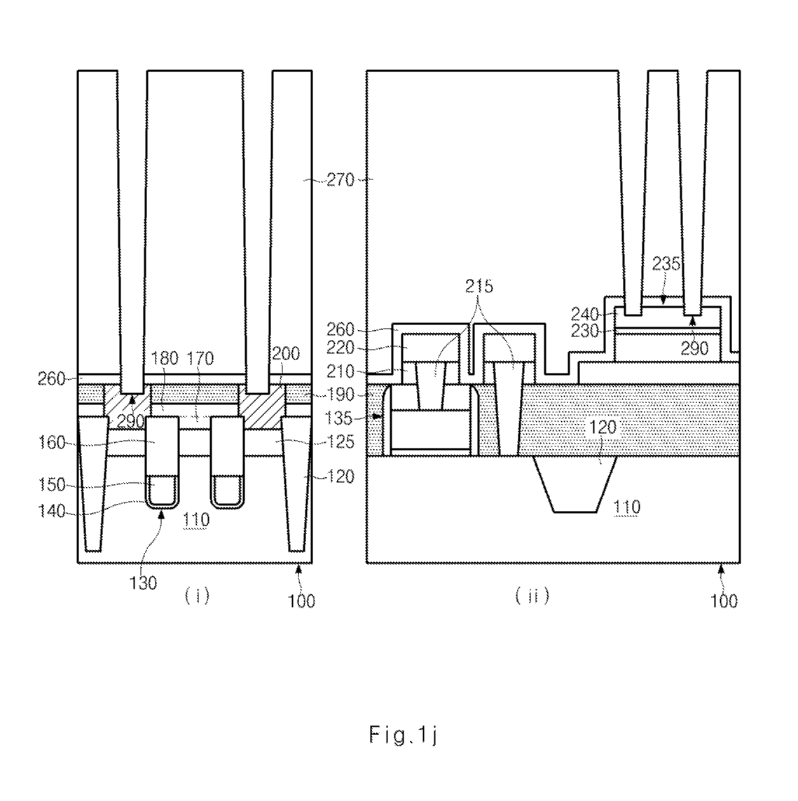

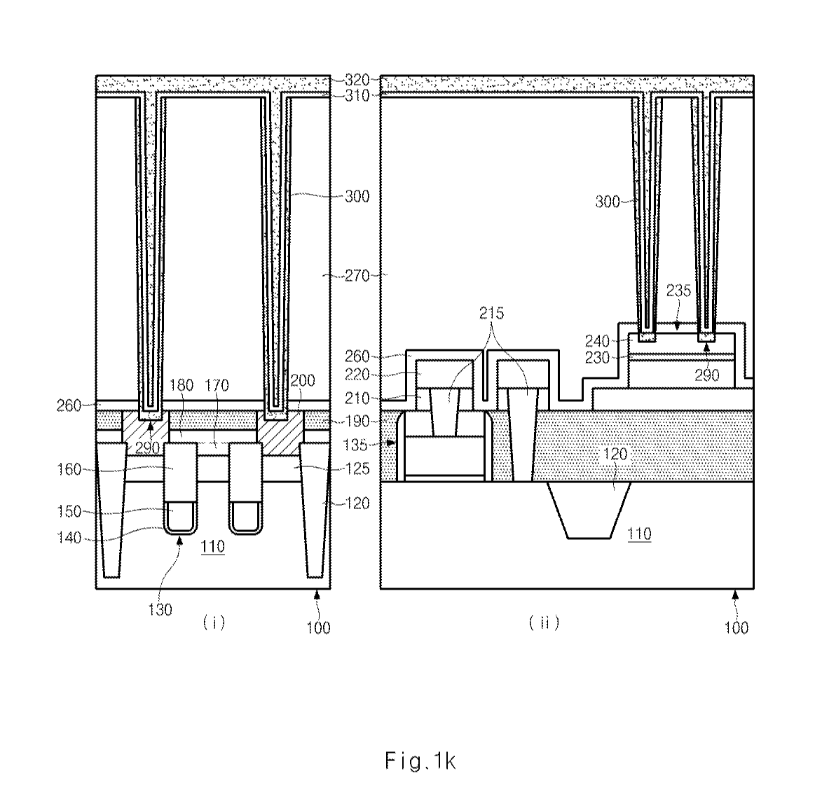

FIGS. 1A to 1K are cross-sectional views illustrating a semiconductor device and a method for manufacturing the same according to an embodiment of the present invention. In each of FIGS. 1A to 1K, (i) shows a cell region, and (ii) shows a periphery region.

Referring to FIG. 1A(i), a device isolation film 120 defining an active region 110 is formed over a semiconductor substrate 100. Thereafter, ions are implanted in the active region 110, so that a source and drain region 125 is formed.

Subsequently, after a photoresist film is formed over the active region 110 and the device isolation film 120, a photoresist pattern (not shown) is formed by an exposure and development process using a mask defining a buried gate region. The active region 110 and the device isolation film 120 are etched using the photoresist pattern as an etch mask, so that a buried gate region 130 is formed.

In addition, an oxidation process is performed in the buried gate region 130 so that an oxide film 140 is formed. After depositing a gate electrode material 150, the gate electrode material 150 and the oxide film 140 are etched back so that only some parts of them are left in the buried gate region 130.

An insulation film is buried in the buried gate region 130. Thereafter, a bit line contact plug 170 and a bit line 180 coupled to the active region 110 are formed.

After the first insulation film 190 is formed over the active region 110 and the bit line 180, the first insulation film 190 is etched until the active region 110 is exposed, and a conductive material is deposited so that a storage node contact plug 200 is formed.

Referring to FIG. 1A(ii), a device isolation film 120 defining the active region 110 is formed over the semiconductor substrate 100, and a peri-gate pattern 135 is formed in the active region 110.

The structure shown in FIG. 1B(i) is identical to that of FIG. 1A(i).

Referring to FIG. 1B(ii), the first insulation film 190 is formed over the peri-gate pattern 135, the device isolation film 120 and the active region 110. In an embodiment, the first insulation film 190 may be formed of an oxide film.

Referring to FIG. 1C(i), a second insulation film 210 is formed over the first insulation film 190 and the storage node contact plug 200. In an embodiment, the second insulation film 210 may be formed of an oxide film.

Referring to FIG. 1C(ii), the second insulation film 210 is formed over the first insulation film 190 and the peri-gate pattern 135.

Referring to FIG. 1D(i), a first metal electrode 220, a dielectric film 230, and a second metal electrode 240 are formed over the second insulation film 210.

Referring to FIG. 1D(ii), a contact plug 215 coupled to the peri-gate pattern 135 or the active region 110 (including a source and drain junction) is formed. In addition, the first metal electrode 220, the dielectric film 230, and the second metal electrode 240 are formed over the contact plug 215 and the second insulation film 210. In an embodiment, the first metal electrode may include tungsten (W), titanium (Ti), titanium nitride (TiN), polymer (Polymer), cobalt (Co) or nickel (Ni).

Referring to FIG. 1E(i), the second metal electrode 240, the dielectric film 230, and the first metal electrode 220 are removed in the cell region.

Referring to FIG. 1E(ii), the second metal electrode 240, the dielectric film 230, and the first metal electrode 220 are etched using a mask defining a metal line as an etch mask, so that a metal line 225 and a reservoir capacitor (or storage capacitor) 235 may be formed.

The structure shown in FIG. 1F(i) is identical to that of FIG. 1E(i).

Referring to FIGS. 1F(i) and 1F(ii), the cell region is opened while the reservoir capacitor 235 is shielded by a mask 250 in the periphery region.

Referring to FIG. 1G(i), in the cell region, the second insulation film 210 is removed.

Referring to FIG. 1G(ii), the second insulation film 210 is patterned using the mask 250, and a stack including the first metal electrode 220, the dielectric film 230 and the second metal electrode 240. Then, the mask 250 is removed. Also, the dielectric film 230 and the second metal electrode 240, except those disposed in a reservoir capacitor region, are removed.

Referring to FIG. 1H(i), an etch stop film 260 is formed over the storage node contact plug 200 and the first insulation film 190.

Referring to FIG. 1H(ii), the etch stop film 260 is formed over the storage capacitor 235, the first metal electrode 220, the second insulation film 210, and the first insulation film 190.

Referring to FIG. 1I, after a third insulation film 270 is formed over the etch stop film 260, a photoresist film (not shown) is formed over the third insulation film 270. In an embodiment, the third insulation film 270 may be formed of a stacked structure of a Tetraethly Orthosilicate (TEOS) film and a Phosposilicate Glass (PSG) film. Thereafter, a photoresist pattern 280 is formed over the third insulation film 270 to define a lower electrode.

Referring to FIG. 1J(i), the third insulation film 270 and the etch stop film 260 are etched using the photoresist pattern 280 as an etch mask until the storage node contact plug 200 is exposed, so that a lower electrode region 290 is formed. Thereafter, the photoresist pattern 280 is removed.

Referring to FIG. 1J(ii), the third insulation film 270 and the etch stop film 260 are etched using the photoresist pattern 280 as an etch mask until the storage capacitor 235 is exposed, so that the lower electrode region 290 is formed. Thereafter, the photoresist pattern 280 is removed.

Referring to FIG. 1K, after a conductive material is deposited over the lower electrode region 290 and the third insulation film 270, the conductive material is etched until the third insulation film 270 is exposed so that a lower electrode 300 is formed. In addition, a dielectric film 310 and an upper electrode 320 are sequentially formed over the lower electrode 300. The reservoir capacitor 235 is connected to the lower electrode 300 (cylinder type capacitor)

As is apparent from the above description, in a semiconductor device and a method for manufacturing the same according to an embodiment of the present invention, a semiconductor device sufficiently endures a high bias by employing a reservoir capacitor such that a planar type MOS capacitor and a cylindrical capacitor are combined. Such a combined reservoir capacitor can have sufficient capacitance even if it is formed in a small area.

The above embodiments of the present invention are illustrative and not limitative. Various alternatives and equivalents are possible. The invention is not limited by the type of deposition, etching polishing, and patterning steps described herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

1-9. (canceled)

10. A semiconductor device comprising:
a first insulation film and a second insulation film formed over a semiconductor substrate including a periphery region;
a gate pattern formed in the first insulation film;
a first reservoir capacitor formed over the second insulation film; and
a second reservoir capacitor coupled to the first reservoir capacitor.

11. The semiconductor device according to claim 10, wherein the first reservoir capacitor includes a MOS-type capacitor.

12. The semiconductor device according to claim 10, wherein the first reservoir capacitor includes a first metal electrode, a dielectric film, and a second metal electrode.

13. The semiconductor device according to claim 12, wherein the first metal electrode includes tungsten (W), titanium (Ti), titanium nitride (TiN), polymer (Polymer), cobalt (Co) or nickel (Ni).

14. The semiconductor device according to claim 10, wherein the second reservoir capacitor includes a cylindrical capacitor.

15. The semiconductor device according to claim 10, the device further comprising:
a contact plug coupled to any of the gate pattern and the semiconductor substrate.

16. The semiconductor device according to claim 15, wherein the contact plug is coupled to a conductive line.

17. A semiconductor device including a reservoir capacitor in a peripheral region, the reservoir capacitor comprising:
a planar type lower capacitor; and
a cylinder type upper capacitor coupled to the planar type lower capacitor.

18. The semiconductor device of claim 17, the device further comprising:
a first metal line coupled to a peri-gate, the peri-gate provided in the peripheral region; and
a second metal line coupled to a source/drain region provided in the peripheral region,
wherein the planar type lower capacitor is provided at the substantially the same level as any of the first metal line and the second metal line.

19. The semiconductor device of claim 17, the device further comprising a cylinder type cell capacitor provided in a cell region,
wherein a top of the cylinder type upper capacitor is provided to be substantially same level to a top of the cylinder type cell capacitor.
